(19) United States
(12) Patent Application Publication
(10) Pub. No.: US 2011/0151227 A1
(43) Pub. Date: Jun. 23, 2011

(54) HIGH-K DIELECTRIC FILMS AND METHODS OF PRODUCING USING TITANIUM-BASED B-DIKETONATE PRECURSORS

(75) Inventors: Paul Raymond Chalker, Wirral (GB); Peter Nicholas Heys, Crewe (GB)

(73) Assignee: SIGMA-ALDRICH CO., St. Louis, MO (US)

(21) Appl. No.: 12/992,942

(22) PCT Filed: May 22, 2009
(86) PCT No.: PCT/US09/45039

§ 371 Date: Mar. 7, 2011

Related U.S. Application Data
(60) Provisional application No. 61/055,695, filed on May 23, 2008.

(51) Int. Cl. C04B 35/48; B32B 15/02; H01L 21/31

(52) U.S. Cl. 428/220; 501/103; 501/126; 438/785; 257/E21.24

(57) ABSTRACT

Methods are provided to form and stabilize high-κ dielectric films by vapor deposition processes using metal-source precursors and titanium-based β-diketonate precursors according to Formula I: Ti(L)ₓ wherein: L is a β-diketonate; and x is 3 or 4. Further provided are methods of improving high-κ gate property of semiconductor devices by using titanium precursors according to Formula I. High-κ dielectric film-forming lattices are also provided comprising titanium precursors according to Formula I.

### CROSS-REFERENCE TO RELATED APPLICATIONS

This patent claims the benefit of U.S. provisional application Ser. No. 61/055,695, filed on 23 May 2008, the disclosure of which is incorporated herein by reference in its entirety. Disclosure of copending U.S. provisional application Ser. No. 61/055,620, filed on 23 May 2008; copending U.S. provisional application Ser. No. 61/055,646, filed on 23 May 2008; copending U.S. provisional application Ser. No. 61/055,594, filed on 23 May 2008; and copending U.S. provisional application Ser. No. 61/105,594, filed on 15 Oct. 2008, are each incorporated herein by reference in their entirety without admission that such disclosures constitute prior art to the present invention.

### FIELD OF THE INVENTION

The present invention relates to methods of forming high-κ dielectric thin metallic films, improving such films, and a lattice capable of forming such films.

### BACKGROUND OF THE INVENTION

Various organometallic precursors are used to form high-κ dielectric thin metal films for use in the semiconductor industry. Various deposition processes are used to form the metal films, such as chemical vapor deposition (“CVD”) or atomic layer deposition (“ALD”), also known at atomic layer epitaxy.

CVD is a chemical process whereby precursors are deposited on a substrate to form a solid thin film. In a typical CVD process, the precursors are passed over a substrate (wafer) within a low pressure or ambient pressure reaction chamber. The precursors react and/or decompose on the substrate surface creating a thin film of deposited material. Volatile by-products are removed by gas flow through the reaction chamber. The deposited film thickness can be difficult to control because it depends on coordination of many parameters such as temperature, pressure, gas flow volumes and uniformity, chemical depletion effects and time.

ALD is a chemical process which separates the precursors during the reaction. The first precursor is passed over the substrate producing a monolayer on the substrate. Any excess unreacted precursor is pumped out of the reaction chamber. A second precursor is then passed over the substrate and reacts with the first precursor, forming a second monolayer of film over the first-formed film on the substrate surface. This cycle is repeated to create a film of desired thickness. ALD film growth is self-limited and based on surface reactions, creating uniform depositions that can be controlled at the nanometer-thickness scale.

Yashima M., et. al. report zirconia-ceria solid solutions and lattice in an abstract presented at the Fall Meeting of the Ceramic Society of Japan, Kanazawa, Japan, Sep. 26-28, 1990 (Paper No. 6-3A07), and at the 108^{th} Annual Meeting of the Japan Institute of Metals, Tokyo, Japan, Apr. 2-4, 1991 (Paper No. 508).

Scott, H. G. reports metastable and equilibrium phase relationships in zirconia-yttria system. [“Phase Relationships in the zirconia-yttria system,” J. Mat. Science. 1975. 10:1527-1535].

International Publication No. WO 02/27063 reports vapor deposition processes using metal oxides, silicates and phosphates, and silicon dioxide.

Zirconia and hafnia have been used to create dielectric films, generally to replace silicon dioxide gates for use in the semiconductor industry. Replacing silicon dioxide with a high-κ dielectric material allows increased gate capacitance without concomitant leakage effects.

Therefore, methods are needed to create and improve high-κ dielectric films by either increasing the dielectric constant, or stabilizing the film to maintain a high dielectric constant, or both.

### SUMMARY OF THE INVENTION

There is now provided a method to form a high-κ dielectric film by a vapor deposition process. The method comprises delivering at least one metal-source precursor and at least one titanium precursor to a substrate, wherein the at least one titanium precursor corresponds in structure to Formula I:

Ti(L)ₓ (Formula I)

wherein:
L is a β-diketonate; and
x is 3 or 4.

There is further provided a method to improve high-κ gate property of a semiconductor device. The method comprises using at least one titanium precursor to form a high-κ dielectric film for use in the semiconductor device, wherein the at least one titanium precursor corresponds in structure to Formula I.

There is further provided a method to stabilize a high-κ dielectric material. The method comprises adding at least one titanium precursor to the high-κ dielectric material, wherein the at least one titanium precursor corresponds in structure to Formula I.

There is further provided a high-κ dielectric film-forming lattice, wherein the lattice is comprised of hafnium oxide, zirconium oxide or mixtures thereof and the lattice contains titanium atoms.

Other embodiments, including particular aspects of the embodiments summarized above, will be evident from the detailed description that follows.

### DETAILED DESCRIPTION OF THE INVENTION

In various aspects of the invention, methods are provided that utilize titanium (III) and/or titanium (IV) precursors as dopants to form high-κ dielectric thin films. The methods of the invention are used to create or grow thin films with an improved high-κ gate property, and thus are able to maintain high dielectric constants. In other aspects of the invention a lattice is provided capable of forming a high-κ gate film.

As used herein, the term “high-κ dielectric” refers to a material, such as a metal-containing film, with a higher dielectric constant (κ) when compared to silicon dioxide (which has a dielectric constant of about 3.7). Typically, a high-κ dielectric film is used in semiconductor manufacturing processes to replace the silicon dioxide gate dielectric. A high-κ dielectric film may be referred to as having a “high-κ gate property” when the dielectric film is used as a gate material and has at least a higher dielectric constant than silicon dioxide.

As used herein, the term “relative permittivity” is synonymous with dielectric constant (κ).

As used herein, the term “vapor deposition process” is used to refer to any type of vapor deposition technique such as CVD or ALD. In various embodiments of the invention, CVD may take the form of liquid injection CVD. In other embodiments, ALD may be either photo-assisted ALD or liquid injection ALD.

As used herein, the term “precursor” refers to an organometallic molecule, complex and/or compound which is deposited or delivered to a substrate to form a thin film by a vapor deposition process such as CVD or ALD.

As used herein, the term “alkyl” refers to a saturated hydrocarbon chain of 1 to 10 carbon atoms in length, such as, but not limited to, methyl, ethyl, propyl and butyl. The alkyl group may be straight-chain or branched-chain. For example, as used herein, propyl encompasses both n-propyl and iso-propyl; butyl encompasses n-butyl, sec-butyl, iso-butyl and tert-butyl.

As used herein, the term “β-diketonate” refers to a compound or complex containing the following moiety:

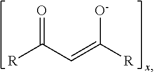

wherein R is an alkyl group and x is the number of β-diketonate moieties attached to typically, a metal center. For example, 2,2,6,6-tetramethyl-3,5-heptanedionate (also known as THD) is a β-diketonate depicted as:

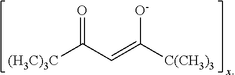

In a first embodiment, a method to form a high-κ dielectric film by a vapor deposition process is provided. The method comprises delivering at least one metal-source precursor and at least one titanium precursor to a substrate, wherein the at least one titanium precursor corresponds in structure to Formula I:

Ti(L)ₓ (Formula I)

wherein:
L is a β-diketonate; and
x is 3 or 4.

In one embodiment L is a β-diketonate such as 2,2,6,6-tetramethyl-3,5-heptanedionate, pentane-2,4-dionate, 1,1,1-trifluoro-2,4-dionate, 1,1,1,5,5,5-hexafluoropentane-2,4-dionate, hexafluoroisopropoxide, 2-dimethylaminoethanolate, 2-methoxyethanolate or 1-methoxy-2-methyl-2-propanolate. In a particular embodiment L is a β-diketonate and x is 4, therefore in this embodiment there are four β-diketonates attached to titanium. In further particular embodiment, the β-diketonate is 2,2,6,6-tetramethyl-3,5-heptanedionate (also known as THD).

Any metal-source precursor suitable for forming a film may be used according to the invention. In a particular embodiment, the at least one metal-source precursor is compatible with the at least one titanium precursor. For example, without limitation, the at least one metal-source precursor may be compatible with the at least one titanium precursor for purposes of depositing a metal oxide film with the composition TiₓM₁₋ₓO_{y} where M is either Hf or Zr; x has a value between about zero and about 0.5; and y has a value less than about 2.

Examples of the at least one metal-source precursor include, without limitation:
a metal amide, such as Hafnium dimethylamide, Zirconium dimethylamide, Hafnium ethylmethylamide, Zirconium ethylmethylamide, Hafnium diethylamide and Zirconium diethylamide;
a metal alkoxide, such as Hafnium t-butoxide, Zirconium t-butoxide, Hafnium i-propoxide, Zirconium i-propoxide, Hafnium bis t-butoxy bis 2-methyl-2-methoxy propoxide, Zirconium bis t-butoxy bis 2-methyl-2-methoxy propoxide, Zirconium bis i-propoxy bis 2-methyl-2-methoxy propoxide, Hafnium 2-methyl-2-methoxy propoxide and Zirconium 2-methyl-2-methoxy propoxide;
a metal β-diketonate (not Ti(THD)₄), such as Hafnium 2,2,6,6-tetramethyl-3,5-heptanedionate, Zirconium 2,2,6,6-tetramethyl-3,5-heptanedionate and Zirconium bis i-propoxy bis 2,2,6,6-tetramethyl-3,5-heptanedionate;
a metal cyclopentadienyl, such as bis methylcyclopentadienyl Hafnium dimethyl, bis methylcyclopentadienyl Zirconium dimethyl, bis methylcyclopentadienyl Hafnium methyl methoxide, bis methylcyclopentadienyl Zirconium methyl methoxide, methylcyclopentadienyl Hafnium tris dimethylamide and methylcyclopentadienyl Zirconium tris dimethylamide.

Therefore, in one embodiment, the high-κ dielectric film formed by a method of the invention may comprise:
(1) hafnium oxide and titanium,
(2) zirconium oxide and titanium,
(3) mixtures of hafnium oxide and zirconium oxide and titanium.

In a particular embodiment, at least one titanium precursor is used in a vapor deposition process with at least one hafnium precursor to create a titanium-doped hafnium oxide film.

In another particular embodiment, at least one titanium precursor is used in a vapor deposition process with at least one zirconium precursor to create a titanium-doped zirconium oxide film.

In another particular embodiment, at least one titanium precursor is used in a vapor deposition process with at least one hafnium precursor and zirconium precursor to create a titanium-doped “mixed” metal oxide film. Therefore, a “mixed” metal oxide film, as used herein, refers to a metal oxide film comprising titanium and hafnium oxide and zirconium oxide.

In one embodiment, the method of the invention creates either hafnium oxide, zirconium oxide or a mixed metal oxide dielectric film that contains from about 0.5 to about 35 atomic metal % titanium. In a particular embodiment the metal oxide or mixed metal oxide film contains from about 5 to about 20 atomic metal % titanium. In a further particular embodiment, the metal oxide or mixed metal oxide film contains from about 8 to about 12 atomic metal % titanium.

In one embodiment, the at least one metal source precursor and/or the at least one titanium precursor may be dissolved in an appropriate hydrocarbon or amine solvent. Appropriate hydrocarbon solvents include, but are not limited to aliphatic hydrocarbons, such as hexane, heptane and nonane; aromatic hydrocarbons, such as toluene and xylene; aliphatic and cyclic ethers, such as diglyme, triglyme and tetraglyme. Examples of appropriate amine solvents include, without limitation, octylamine and N,N-dimethyldodecylamine. For example, a precursor may be dissolved in toluene to yield a 0.05 to 1M solution.

In a particular embodiment, the at least one titanium precursor is dissolved in an organic solvent, such as toluene, heptane, octane, nonane or tetrahydrofuran (THF).

The titanium-doped films of the invention can be formed by chemical vapor deposition. In a particular embodiment, the chemical vapor deposition is liquid injection chemical vapor deposition.

Alternatively, the titanium-doped films of the invention can be formed by atomic layer deposition. In a particular embodiment, the atomic layer deposition is photo-assisted atomic layer deposition. And in another particular embodiment, the atomic layer deposition is liquid injection atomic layer deposition.

In one embodiment of the invention, each precursor is deposited and/or delivered onto a substrate in pulses alternating with pulses of an oxygen source. Any suitable oxygen source may be used, for example, H₂O, O₂ or ozone.

In a particular embodiment, each precursor is deposited onto a substrate in pulses with a continuous supply of an oxygen source such as H₂O, O₂ or ozone.

In one embodiment of the invention, the titanium-doped high-κ dielectric film has a relative permittivity of about 20 to about 100, particularly from about 40 to about 70. Further, the high-κ dielectric film is capable of maintaining a relative permittivity of about 20 to about 100 at frequencies of about 1 KHz to about 1 GHz.

A variety of substrates can be used in the methods of the present invention. For example, the precursors according to Formula I may be deposited on substrates such as, but not limited to, silicon, silicon oxide, silicon nitride, tantalum, tantalum nitride, or copper.

In another embodiment of the invention, a method is provided to improve the high-κ gate property of a semiconductor device. The method comprises using at least one titanium precursor to form a high-κ dielectric film for use in the semiconductor device, wherein the at least one titanium precursor corresponds in structure to Formula I above.

Including at least one titanium precursor according to Formula I in a metal oxide film improves the high-κ gate property by either increasing the dielectric constant, allowing longer maintenance of a high dielectric constant or both, when compared to the particular metal oxide film without the at least one titanium precursor. This improves the high-κ gate property of the semiconductor device by increasing gate capacitance and improving permittivity for faster transistors and smaller devices.

For example, the dielectric constant can be increased about 20 to about 50 units by using at least one titanium precursor according to Formula I; or a high dielectric constant can be maintained at about 1 KHz to about 1 GHz, when compared to not using at least one titanium precursor according to Formula I.

In another embodiment of the invention, a method is provided to stabilize a high-κ dielectric material. The method comprises adding at least one titanium precursor to the high-κ dielectric material wherein the at least one titanium precursor corresponds in structure to Formula I above. The term “stabilize” refers generally to altering the high-κ dielectric material such that the high-κ dielectric material is able to maintain a high dielectric constant at frequencies of about 1 KHz to about 1 GHz.

Therefore, in one embodiment of the invention, the titanium-doped high-κ dielectric film has a relative permittivity of about 20 to about 100, particularly from about 40 to about 70. Further, the high-κ dielectric film is capable of maintaining a relative permittivity of about 20 to about 100 at frequencies of about 1 KHz to about 1 GHz.

The high-κ dielectric material may be any material wherein stabilization is needed to improve or maintain a high dielectric constant. For example, the high-κ dielectric material may be provided by a film composed of hafnium oxide, zirconium oxide, or a “mixed” metal oxide, for example, a hafnium oxide and zirconium oxide mixture.

Without being bound by theory, it is believed that doping hafnium and/or zirconium with a +3-oxidation-state rare earth element causes or permits ‘dielectric relaxation’ in the film-forming materials or film thereby formed. High frequencies cause the dielectric constant (or relative permittivity) of the material to decrease, which is known as dielectric relaxation. It is hypothesized that dielectric relaxation occurs because substitution of hafnium and/or zirconium with the +3 element in the lattice causes an oxygen vacancy in order to maintain balanced charge. In order to improve the dielectric constant and/or maintain the dielectric constant at high frequencies, a hafnium oxide, zirconium oxide, or mixed oxide film can be created using a precursor as disclosed herein such that titanium (IV) is incorporated into the lattice.

Thus in one embodiment of the invention, the high-κ dielectric material is stabilized by stabilizing the metastable phase of the metal used. For example, and without being bound by theory, pure zirconium oxide and hafnium oxide exhibit a stable monoclinic crystalline phase with dielectric constant typically in the range of about 18 to about 22. The metastable phases, such as tetragonal and cubic crystal structures of these materials, have high permittivities. Therefore, it is hypothesized that in order to stabilize the metastable phases, some of the Group IV metal may be replaced with one or more titanium precursors of Formula I which can adopt a +4 charge and may obviate the formation of charged oxygen ion vacancies.

Further, the use of titanium precursor(s) to stabilize different phases also has implications for radiation hardness, as the resistance to radiation can be increased which is very useful for space applications where resistance to degradation by various forms of radiation is key to device lifetimes and efficiencies. Therefore, these stabilized high-κ dielectric materials are useful in semiconductor devices and are useful for computer memory and logic applications, such as dynamic random access memory (DRAM) and complementary metal oxide semi-conductor (CMOS) circuitry.

In another embodiment of the invention, a high-κ dielectric film-forming lattice is provided. The lattice, which is an array of points repeating periodically in three dimensions, is comprised of hafnium oxide, zirconium oxide or mixtures thereof; and the lattice contains titanium atoms. The atoms are arranged upon the points of the lattice. The points form unit cells that fill the space of the lattice.

In addition to phase stabilization discussed above, without being bound by theory, the titanium may also have an effect on the polarizability of the unit cell, i.e. the relative tendency of a charge distribution, like the electron cloud of an atom or molecule, to be distorted from its normal shape by an external electric field, which may be caused by the presence of a nearby ion or dipole. With titanium present it is hypothesized that this polarizability is enhanced which may impact the dielectric constant value beneficially by increasing or maintaining the dielectric constant longer. Polarizability of the unit cell coupled with stabilization of the highest dielectric constant phase of each metal oxide may ensure that the maximum dielectric constant value can be obtained from the particular material system in use.

The titanium atoms for the lattice are provided from at least one titanium precursor corresponding in structure to Formula I.

The titanium may be substitutional on the Group IV atomic sites or located interstitially, as interstitial inclusions.

The lattice is capable of forming a high-κ dielectric film by a vapor deposition process, such as CVD or ALD.

In one embodiment, the film formed by the lattice has a thickness from about 0.2 nm to about 500 nm; and contains from about 0.5 to about 35 atomic metal % titanium. In a particular embodiment the metal oxide or mixed metal oxide film contains from about 5 to about 20 atomic metal % titanium. In a further particular embodiment, the metal oxide or mixed metal oxide film contains from about 8 to about 12 atomic metal % titanium.

In another embodiment, the film formed by the lattice has a relative permittivity of about 20 to about 100, particularly from about 40 to about 70. Further, the film formed is capable of maintaining a relative permittivity of about 20 to about 100 at frequencies of about 1 KHz to about 1 GHz.

All patents and publications cited herein are incorporated by reference into this application in their entirety.

The words “comprise”, “comprises”, and “comprising” are to be interpreted inclusively rather than exclusively.

What is claimed is:

1. A method to form a high-κ dielectric film by a vapor deposition process, the method comprising delivering at least one metal-source precursor and at least one titanium precursor to a substrate, wherein the at least one titanium precursor corresponds in structure to Formula I:
Ti(L)ₓ (Formula I)
wherein:
L is a β-diketonate; and
x is 3 or 4.

2. The method of claim 1, wherein L is a β-diketonate independently selected from the group consisting of 2,2,6,6-tetramethyl-3,5-heptanedionate, pentane-2,4-dionate; 1,1,1-trifluoro-2,4-dionate, 1,1,1,5,5,5-hexafluoropentane-2,4-dionate, hexafluoroisopropoxide, 2-dimethylaminoethanolate, 2-methoxyethanolate and 1-methoxy-2-methyl-2-propanolate; and x is 4.

3. The method of claim 1, wherein the at least one titanium precursor is

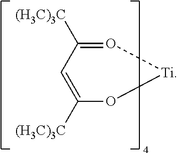

4. The method of claim 1, wherein the high-κ dielectric film comprises hafnium oxide and titanium; or zirconium oxide and titanium; or mixture of hafnium oxide and zirconium oxide and titanium.

5. The method of claim 4, wherein the hafnium oxide, zirconium oxide or mixture thereof contains from about 0.5 to about 35 atomic metal % titanium.

6. The method of claim 5, wherein the hafnium oxide, zirconium oxide or mixture thereof contains from about 5 to about 20 atomic metal % titanium.

7. The method of claim 5, wherein the hafnium oxide, zirconium oxide or mixture thereof contains from about 8 to about 12 atomic metal % titanium.

8. The method of claim 1, wherein the vapor deposition process is chemical vapor deposition.

9. The method of claim 8, wherein the chemical vapor deposition is liquid injection chemical vapor deposition.

10. The method of claim 1, wherein the vapor deposition process is atomic layer deposition.

11. The method of claim 10, wherein the atomic layer deposition is photo-assisted atomic layer deposition.

12. The method of claim 10, wherein the atomic layer deposition is liquid injection atomic layer deposition.

13. The method of claim 1, wherein the at least one titanium precursor is dissolved in an organic solvent.

14. The method of claim 13, wherein the organic solvent is selected from the group consisting of toluene, heptane, octane, nonane and tetrahrydrofuran.

15. The method of claim 1, wherein each precursor is deposited onto the substrate in pulses alternating with pulses of an oxygen source.

16. The method of claim 15, wherein the oxygen source is H₂O, O₂ or ozone.

17. The method of claim 1, wherein each precursor is deposited onto the substrate in pulses with a continuous supply of an oxygen source.

18. The method of claim 17, wherein the oxygen source is H₂O, O₂ or ozone.

19. The method of claim 1, wherein the at least one metal-source precursor is compatible with the titanium precursor.

20. The method of claim 1, wherein the at least one metal-source precursor is selected from the group consisting of
a metal amide selected from the group consisting of Hafnium dimethylamide, Zirconium dimethylamide, Hafnium ethylmethylamide, Zirconium ethylmethylamide, Hafnium diethylamide and Zirconium diethylamide;
a metal alkoxide selected from the group consisting of Hafnium t-butoxide, Zirconium t-butoxide, Hafnium i-propoxide, Zirconium i-propoxide, Hafnium bis t-butoxy bis 2-methyl-2-methoxy propoxide, Zirconium bis t-butoxy bis 2-methyl-2-methoxy propoxide, Zirconium bis i-propoxy bis 2-methyl-2-methoxy propoxide, Hafnium 2-methyl-2-methoxy propoxide and Zirconium 2-methyl-2-methoxy propoxide;
a metal β-diketonate selected from the group consisting of Hafnium 2,2,6,6-tetramethyl-3,5-heptanedionate, Zirconium 2,2,6,6-tetramethyl-3,5-heptanedionate and Zirconium bis i-propoxy bis 2,2,6,6-tetramethyl-3,5-heptanedionate;
a metal cyclopentadienyl selected from the group consisting of bis methylcyclopentadienyl Hafnium dimethyl, bis methylcyclopentadienyl Zirconium dimethyl, bis methylcyclopentadienyl Hafnium methyl methoxide, bis methylcyclopentadienyl Zirconium methyl methoxide, methylcyclopentadienyl Hafnium tris dimethylamide and methylcyclopentadienyl Zirconium tris dimethylamide.

21. The method of claim 1, wherein the high-κ dielectric film has a relative permittivity of about 20 to about 100.

22. The method of claim 1, wherein the high-κ dielectric film can maintain a relative permittivity of about 20 to about 100 at frequencies of about 1 KHz to about 1 GHz.

23. The method of claim 1, wherein the high-κ dielectric film is used for memory and logic applications in silicon chips.

24. A method to improve high-κ gate property of a semiconductor device, the method comprising using at least one titanium precursor to form a high-κ dielectric film for use in the semiconductor device, wherein the at least one titanium precursor corresponds in structure to Formula I:
Ti(L)ₓ (Formula I)
wherein:
L is a β-diketonate; and
x is 3 or 4.

25. The method of claim 24, wherein L is a β-diketonate independently selected from the group consisting of 2,2,6,6-tetramethyl-3,5-heptanedionate, pentane-2,4-dionate; 1,1,1-trifluoro-2,4-dionate, 1,1,1,5,5,5-hexafluoropentane-2,4-dionate, hexafluoroisopropoxide, 2-dimethylaminoethanolate, 2-methoxyethanolate and 1-methoxy-2-methyl-2-propanolate; and x is 4.

26. The method of claim 24, wherein the high-κ dielectric film comprises hafnium oxide containing titanium; zirconium oxide containing titanium; or mixture of hafnium oxide and zirconium oxide containing titanium.

27. The method of claim 24, wherein the high-κ dielectric film has a relative permittivity of about 20 to about 100.

28. The method of claim 24, wherein the high-κ dielectric film can maintain a relative permittivity of about 20 to about 100 at frequencies of about 1 KHz to about 1 GHz.

29. The method of claim 24, wherein the high-κ dielectric film is formed by chemical vapor deposition or atomic layer deposition.

30. A method to stabilize a high-κ dielectric material, the method comprising adding at least one titanium precursor to the high-κ dielectric material wherein the at least one titanium precursor corresponds in structure to Formula I:
Ti(L)ₓ (Formula I)
wherein:
L is a β-diketonate; and
x is 3 or 4.

31. The method of claim 30, wherein the high-κ dielectric material is hafnium oxide, zirconium oxide or a mixture of hafnium oxide and zirconium oxide.

32. The method of claim 31, wherein to stabilize the high-κ dielectric material a hafnium oxide and/or zirconium oxide metastable phase is maintained.

33. The method of claim 31, wherein stabilization of a hafnium oxide, zirconium oxide or mixture thereof results in a relative permittivity of about 20 to about 100.

34. The method of claim 31, wherein stabilization of a hafnium oxide, zirconium oxide or mixture thereof results in a relative permittivity of about 25 to about 100 at frequencies of about 1 KHz to about 1 GHz.

35. The method of claim 30, wherein the stabilized high-κ dielectric material is used in a semiconductor device.

36. A high-κ dielectric film-forming lattice, wherein the lattice is comprised of zirconium oxide, hafnium oxide, or mixture thereof and the lattice contains titanium atoms.

37. The high-κ dielectric film-forming lattice of claim 36, wherein the titanium atoms are substitutionally part of the lattice or the titanium atoms are part of the lattice as interstitial inclusions.

38. The high-κ dielectric film-forming lattice of claim 36, wherein the titanium atoms are provided from at least one titanium precursor corresponding in structure to Formula I:
Ti(L)ₓ (Formula I)
wherein:
L is a β-diketonate; and
x is 3 or 4.

39. The high-κ dielectric film-forming lattice of claim 38, wherein L is a β-diketonate independently selected from the group consisting of 2,2,6,6-tetramethyl-3,5-heptanedionate, pentane-2,4-dionate, 1,1,1-trifluoro-2,4-dionate, 1,1,1,5,5,5-hexafluoropentane-2,4-dionate, hexafluoroisopropoxide, 2-dimethylaminoethanolate, 2-methoxyethanolate and 1-methoxy-2-methyl-2-propanolate; and
x is 4.

40. The high-κ dielectric film-forming lattice of claim 36, wherein the film formed has a thickness from about 0.2 nm to about 500 nm.

41. The high-κ dielectric film forming lattice of claim 36, wherein the film formed has a relative permittivity of about 20 to about 100.

42. The high-κ dielectric film forming lattice of claim 36, wherein the film formed has a relative permittivity of about 20 to about 100 at frequencies of about 1 KHz to about 1 GHz.
